(19) United States
(12) Patent Application Publication
(10) Pub. No.: US 2010/0326513 A1
(43) Pub. Date: Dec. 30, 2010

(54) INVERSE OPAL STRUCTURE HAVING DUAL POROSITY, METHOD OF MANUFACTURING THE SAME, DYE-SENSITIZED SOLAR CELL, AND METHOD OF MANUFACTURING THE DYE-SENSITIZED SOLAR CELL

(75) Inventors: Joo-Wook LEE, Suwon-si (KR); Ji Man Kim, Suwon-si (KR); Sung Soo Kim, Suwon-si (KR); Mingshi Jin, Suwon-si (KR)

Correspondence Address: CHRISTIE, PARKER & HALE, LLP, PO BOX 7068, PASADENA, CA, 91109-7068, US

(73) Assignee: Samsung SDI Co., Ltd., Suwon-si (KR)

(21) Appl. No.: 12/783,609

(22) Filed: May 20, 2010

(30) Foreign Application Priority Data
Jun. 29, 2009 (KR) 10-2009-0058321

(51) Int. Cl. H01L 31/0236; H01L 31/18; B32B 3/26; H01L 21/20

(52) U.S. Cl. 136/256; 438/71; 428/315.5; 438/486; 257/E31.13; 257/E21.09

(57) ABSTRACT

An inverse opal structure having dual porosity, a method of manufacturing the inverse opal structure, a dye-sensitized solar cell, and a method of manufacturing the dye-sensitized solar cell improve the light scattering effects of an included light scattering layer and improve functions of included electrodes. The inverse opal structure includes a plurality of first pores regularly arranged in a photonic crystal structure and a plurality of second pores formed on walls of the first pores in which the second pores have a nano-sized diameter.

### CROSS-REFERENCE TO RELATED APPLICATION

This application claims the benefit of Korean Patent Application No. 10-2009-0058321, filed Jun. 29, 2009, in the Korean Intellectual Property Office, the disclosure of which is incorporated herein by reference.

### BACKGROUND OF THE INVENTION

1. Field of the Invention

Embodiments of the invention relate to an inverse opal structure having dual porosity, a method of manufacturing the inverse opal structure, a dye-sensitized solar cell, and a method of manufacturing the dye-sensitized solar cell.

2. Description of the Related Art

A dye sensitized solar cell includes a photoanode including a semiconductor oxide on which photosensitive dye molecules are adsorbed, an electrolyte including reduction-oxidation (redox) ion pairs, and a counter electrode coated with a platinum (Pt) catalyst. Iodine-based (I⁻/I₃⁻) redox ion pairs are mainly used for transporting electrons in an electrolyte of a dye-sensitized solar cell.

When the dye-sensitized solar cell is exposed to light, photosensitive dye molecules are excited to an excited state and release electrons. Then, the released electrons are injected into the semiconductor oxide and transported to a counter electrode through an external circuit. Meanwhile, dye molecules that lost electrons obtain electrons by oxidation of I⁻ to I₃⁻ contained in the electrolyte. The oxidized redox ion pairs are reduced by the Pt catalyst coated on the surface of the counter electrode, and the reduced redox ion pairs reduce the oxidized dye so as to be excited again.

The light absorptive capacity and the amount of electrons transferred to the photoanode of the dye-sensitized solar cell depend on the adsorptive capacity of the dye adsorbed on the semiconductor oxide. Generally, the photoanode includes a light absorbing layer and a light scattering layer. The light absorbing layer includes TiO₂ particles having an average diameter of about 20 nm in order to increase the amount of the adsorbed dye, and the light scattering layer includes particles having an average diameter ranging from about 300 nm to about 400 nm. The light scattering layer scatters light that has a long wavelength and passed through the light absorbing layer so that the absorption of light having a long wavelength increases.

Meanwhile, a TiO₂ inverse opal structure in which a plurality of sphere shaped pores are regularly arranged absorbs or scatters light of a particular wavelength, and thus has been used in a variety of fields. In particular, research is being conducted into using such inverse opal structure as a light scattering thin film or an electrode in a dye-sensitized solar cell. However, despite its optical properties, the specific surface area of the TiO₂ inverse opal structure is too small to be used in dye-sensitized solar cells.

### SUMMARY OF THE INVENTION

One or more embodiments of the present invention include an inverse opal structure having dual porosity, a method of manufacturing the inverse opal structure, a dye-sensitized solar cell, and a method of manufacturing the dye-sensitized solar cell.

Additional aspects will be set forth in part in the description which follows and, in part, will be apparent from the description, or may be learned by practice of the presented embodiments.

According to one or more embodiments of the present invention, an inverse opal structure includes: a plurality of first pores regularly arranged in a photonic crystal structure; and a plurality of second pores formed on walls of the first pores and having a nano-sized diameter.

According to aspects of the present invention, the first pores may have a spherical shape, the first pores may have an average diameter ranging from about 200 nm to about 400 nm, and the second pores may have an average diameter ranging from about 2 nm to about 6 nm.

According to aspects of the present invention, the inverse opal structure may have a specific surface area ranging from about 50 m²/g to about 100 m²/g.

According to aspects of the present invention, the inverse opal structure may include a semiconductor oxide, such as TiO₂ or ZnO.

According to one or more embodiments of the present invention, a method of manufacturing an inverse opal structure includes: arranging a plurality of photonic crystal particles in a regular pattern; coating a mixture solution including a semiconductor oxide precursor and a surfactant on the photonic crystal particles to fill the space between the photonic crystal particles; crystallizing the semiconductor oxide; removing the photonic crystal particles; and removing the surfactant.

According to aspects of the invention, a plurality of first pores may be formed by the removing of the photonic crystal particles, and a plurality of second pores may be formed by the removing of the surfactant. According to aspects of the invention, the second pores may be formed on walls of each of the first pores.

According to aspects of the invention, the photonic crystal particles may include of poly(methyl methacrylate) (PMMA), poly styrene, and/or silica.

According to aspects of the invention, the photonic crystal particles may be formed of PMMA or poly styrene, and the crystallizing of the semiconductor oxide and the removing of the photonic crystal particles and the surfactant may be performed by heat-treatment. According to aspects of the invention, the photonic crystal particles may be formed of silica, and the crystallizing of the semiconductor oxide and the removing of the surfactant may be performed by the heat-treatment, and the removing of the photonic crystal particles may be performed by etching.

According to one or more embodiments of the present invention, a dye-sensitized solar cell includes: a transparent conductive substrate; a light absorbing layer including TiO₂ and formed on the transparent conductive substrate; and a light scattering layer formed on the light absorbing layer, the light scattering layer having an inverse opal structure including a plurality of first pores regularly arranged in a photonic crystal structure, and a plurality of second pores formed on walls of the first pores, the second pores having a nano-sized diameter.

According to one or more embodiments of the present invention, a method of manufacturing a dye-sensitized solar cell includes: forming a light absorbing layer including TiO₂ on a transparent conductive substrate; forming a light scattering layer on the light absorbing layer, the forming of the light scattering layer comprising: arranging a plurality of photonic crystal particles regularly on the light absorbing layer, coating a mixture solution including a TiO₂ precursor and a surfactant on the photonic crystal particles to fill spaces between the photonic crystal particles, and crystallizing TiO₂ from the TiO₂ precursor, removing the photonic crystal particles, and removing the surfactant.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 schematically shows an inverse opal structure according to an embodiment of the invention;

FIG. 2 is an enlarged view of portion A of FIG. 1;

FIGS. 3 to 6 illustrate a method of manufacturing a thin film inverse opal structure according to another embodiment of the invention;

FIG. 7 schematically shows a dye-sensitized solar cell according to another embodiment of the invention;

FIG. 8 is an enlarged view of portion C of FIG. 7; and

FIGS. 9 to 12 illustrate a method of manufacturing a dye-sensitized solar cell shown in FIG. 7 according to another embodiment of the invention.

### DETAILED DESCRIPTION OF THE EMBODIMENTS

Reference will now be made in detail to the embodiments of the invention, examples of which are illustrated in the accompanying drawings, wherein like reference numerals refer to the like elements throughout. The embodiments are described below in order to explain the invention by referring to the figures. It will be understood that when an element such as a layer, film, region, or substrate is referred to as being “formed on” or “disposed on” another element, it can be disposed directly on the other element, or intervening elements may also be present. In contrast, when an element is referred to as being “formed directly on” or “disposed directly on” another element, there are no intervening elements present.

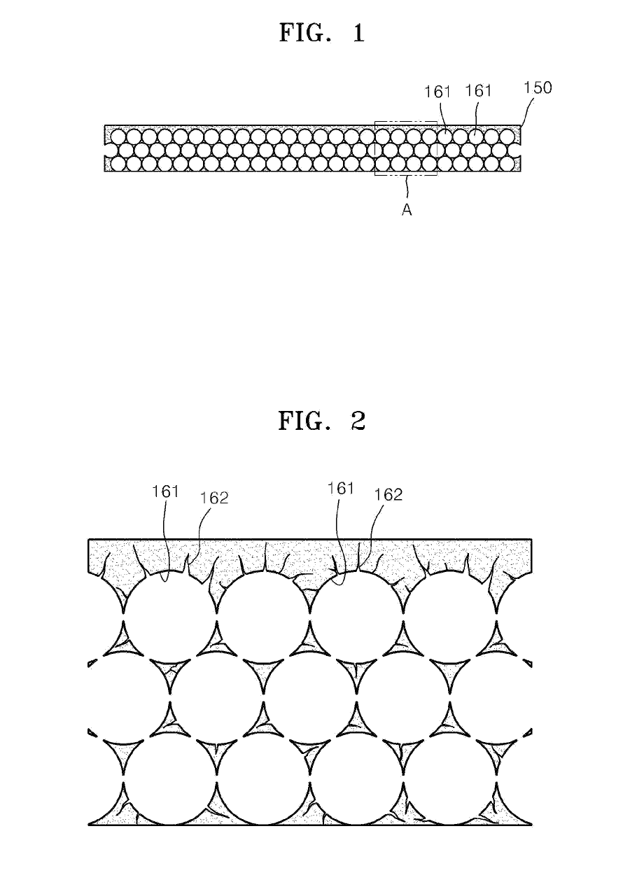

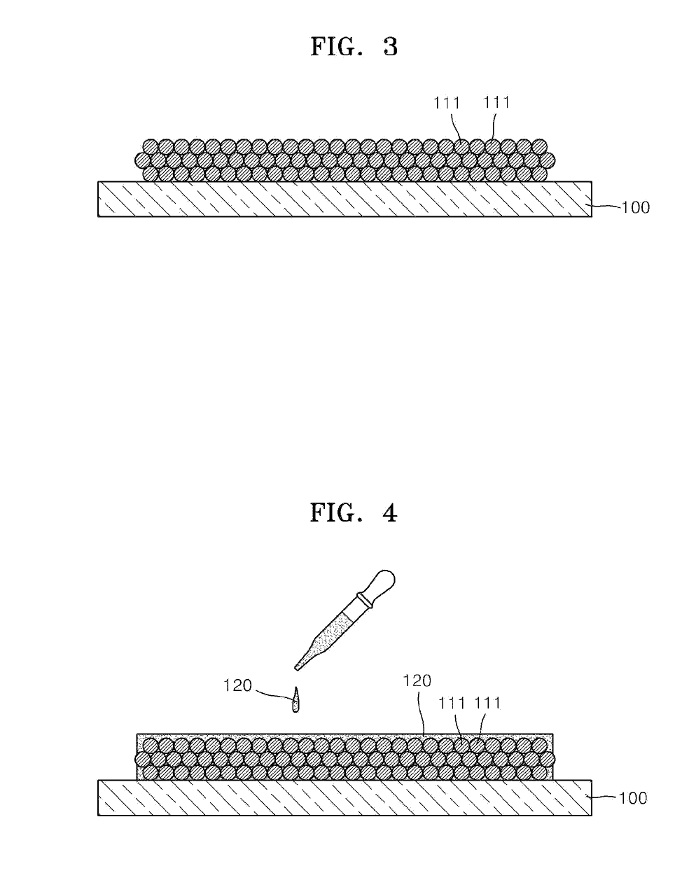

FIG. 1 schematically shows an inverse opal structure 150 according to an embodiment of the invention. FIG. 2 is an enlarged view of portion A of FIG. 1. Referring to FIGS. 1 and 2, the inverse opal structure 150 includes a plurality of first pores 161 and a plurality of second pores 162. The inverse opal structure 150 may also include a semiconductor oxide. The semiconductor oxide may be TiO₂ or ZnO, but the invention is not limited thereto.

The first pores 161 are regularly arranged in a photonic crystal structure and may have a spherical shape and an average diameter ranging from about 200 nm to about 400 nm. The second pores 162 are formed in the wall of each of the first pores 161, and have a nano-sized diameter. The second pores 162 may have an average diameter ranging from about 2 nm to about 6 nm. The average diameter of the second pores 162 may be measured at the surface of the first pores 161, but aspects are not limited thereto. The second pores 162 may have a conical, cleft structure, nano-fissure structure, or a dendritic structure extending away from the surfaces of the first pores 161, but aspects are not limited thereto. Or, described another way, the first pores 161 may be defined by a surface having a high surface roughness, the surface roughness being provided by the second pores 162. The inverse opal structure 150 may have a large specific surface area ranging from about 50 m²/g to about 100 m²/g.

Since the inverse opal structure 150 has dual porosity provided by the first pores 161 and the nano-sized second pores 162 formed on the wall of each of the first pores 161, the specific surface area of the inverse opal structure 150 may be greater than that of an inverse opal structure including only the first pores 161.

The inverse opal structure 150 may be manufactured according to the following method. A plurality of photonic crystal particles are uniformly dispersed on, for example, a funnel. The photonic crystal particles may have a spherical shape and may be poly(methyl methacrylate) (PMMA), polystyrene, and/or silica, but the invention is not limited thereto. The photonic crystal particles may have an average diameter ranging from about 200 nm to about 400 nm. Since the photonic crystal particles are uniformly dispersed on the funnel, the photonic crystal particles are regularly arranged, and are used as a template for manufacturing the inverse opal structure 150 according to aspects of the invention.

Then, a mixture solution including a semiconductor oxide precursor and a surfactant is coated on the photonic crystal particles regularly arranged on the funnel. The semiconductor oxide precursor may be a TiO₂ precursor, a ZnO precursor, or the like, and the surfactant may be PLURONIC® P123 from BASF, cetyltrimethylammonium bromide (CTABr), or the like, but aspects are not limited thereto. The amount of the surfactant based on the amount of the semiconductor oxide precursor may be in the range of about 25 weight % to about 45 weight %. For example, the amount of the surfactant based on the amount of the semiconductor oxide precursor may be about 35 weight %. As such, when the mixture solution of the semiconductor oxide precursor and the surfactant is coated on the photonic crystal particles, the mixture solution fills the spaces between the photonic crystal particles.

Then, the mixture solution including the semiconductor oxide precursor and the surfactant and filled in the spaces between the photonic crystal particles is aged at a relatively low temperature, e.g., at about 4° C., for a time period, e.g., of about 5 days. During the aging process, the surfactant contained in the mixture solution migrates to the peripheral area of the surface of the photonic crystal particles.

Then, the coated photonic crystal particles are heat-treated at a temperature, of about 400° C., for a time period of about 1 hour thereby crystallizing the semiconductor oxide contained in the mixture solution and removing the photonic crystal particles and the surfactant. If the photonic crystal particles are formed of PMMA or polystyrene, the crystallization of the semiconductor oxide and the removal of the photonic crystal particles and the surfactant may be simultaneously performed by the heat-treatment. The surfactant formed on the surface of the photonic crystal particles may be removed while the photonic crystal particles are removed by the heat-treatment.

If the photonic crystal particles are formed of silica, the crystallization of the semiconductor oxide and the removal of the surfactant may be performed by the heat-treatment, and the removal of the photonic crystal particles may be performed by using an etchant, e.g., a NaOH solution.

As such, in the inverse opal structure 150 obtained by the crystallization of the semiconductor oxide and the removal of the photonic crystal particles and the surfactant, a plurality of first pores 161 are formed by the removal of the photonic crystal particles, and a plurality of second pores 162 are formed by the removal of the surfactant. The first pores 161 may have an average diameter ranging from about 200 nm to about 400 nm corresponding to the size of the photonic crystal particles, and the second pores 162 may be formed on the walls of the first pores 161 to have an average diameter ranging from about 2 nm to about 6 nm. The second pores 162 may have a conical, cleft structure, nano-fissure structure, or a dendritic structure extending away from the surfaces of the first pores 161 into the inverse opal structure, but aspects are not limited thereto. Or, described another way, the first pores 161 may be defined by a surface having a high surface roughness, the surface roughness being provided by the second pores 162.

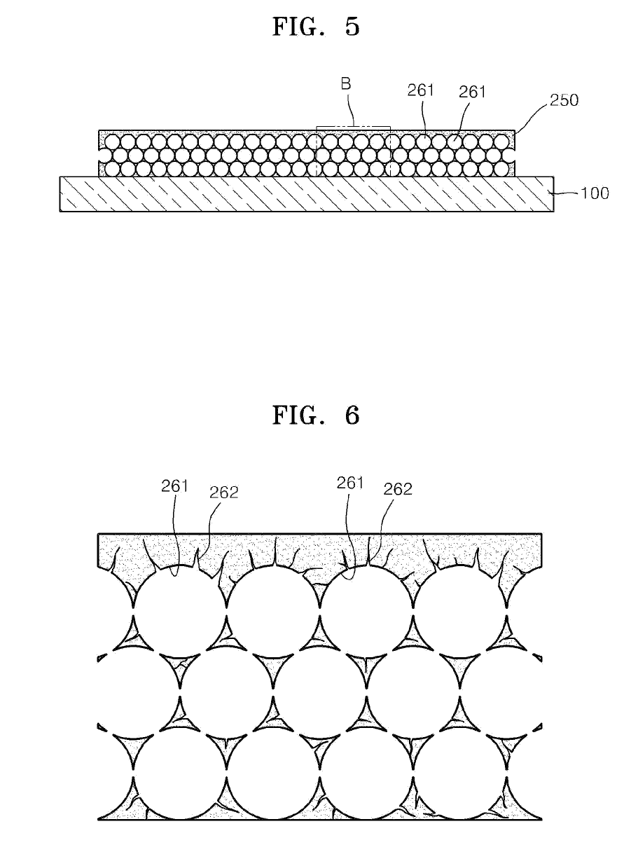

FIGS. 3 to 6 are views that illustration a method of manufacturing an inverse opal structure according to another embodiment of the invention. Referring to FIG. 3, a plurality of photonic crystal particles 111 is regularly disposed on a substrate 100. The photonic crystal particles 111 may be regularly arranged on the substrate 100 using an evaporation induced self assembly (EISA), or the like. The photonic crystal particles 111 may have a spherical shape with an average diameter ranging from about 200 nm to about 400 nm. The photonic crystal particles may be formed of poly(methyl methacrylate) (PMMA), poly styrene, silica, or the like.

Referring to FIG. 4, a mixture solution 120 including a semiconductor oxide precursor and a surfactant is coated on the photonic crystal particles 111 regularly arranged on the substrate 100. The semiconductor oxide precursor may be a TiO₂ precursor, a ZnO precursor, or the like, and the surfactant may be PLURONIC® P123 from BASF, cetyltrimethylammonium bromide (CTABr), or the like, but the invention is not limited thereto. The amount of the surfactant based on the amount of the semiconductor oxide precursor may be in the range of about 25 weight % to about 45 weight %. As such, when the mixture solution 120 of the semiconductor oxide precursor and the surfactant is coated on the photonic crystal particles 111, the mixture solution 120 fills the spaces between the photonic crystal particles 111. Then, the mixture solution 120 including the semiconductor oxide precursor and the surfactant and filled in the spaces between the photonic crystal particles 111 is aged at a relatively low temperature of about 4° C. for a time period of about 5 days. During the aging process, the surfactant contained in the mixture solution 120 is transferred to the peripheral area of the surface of the photonic crystal particles 111.

Finally, referring to FIGS. 5 and 6, the resultant shown in FIG. 4 is heat-treated at a temperature of about 400° C. for a time period of about 1 hour thereby crystallizing the semiconductor oxide contained in the mixture solution 120 and removing the photonic crystal particles 111 and the surfactant. FIG. 6 is an enlarged view of portion B of FIG. 5. If the photonic crystal particles 111 are formed of PMMA or polystyrene, the crystallization of the semiconductor oxide and the removal of the photonic crystal particles 111 and the surfactant may be simultaneously performed by the heat-treatment. The surfactant formed on the surface of the photonic crystal particles 111 is removed while the photonic crystal particles 111 are removed by the heat-treatment. If the photonic crystal particles 111 are formed of silica, the crystallization of the semiconductor oxide and the removal of the surfactant may be performed by the heat-treatment, and the removal of the photonic crystal particles 111 may be performed by using an etchant, e.g., a NaOH solution.

An inverse opal structure 250 is formed on the substrate 100 by the crystallization of the semiconductor oxide and the removal of the photonic crystal particles 111 and the surfactant. In the inverse opal structure 250, a plurality of first pores 261 are formed by removing the photonic crystal particles 111, and a plurality of second pores 262 are formed by removing the surfactant. Accordingly, the second pores 262 are formed on the wall of each of the first pores 261 by the removal of the surfactant as shown in FIG. 6. The first pores 261 may have an average diameter ranging from about 200 nm to about 400 nm corresponding to the size of the photonic crystal particles 111, and the second pores 262 may be formed on the walls of the first pores 261 to have an average diameter ranging from about 2 nm to about 6 nm. The second pores 262 may have a conical, cleft structure, nano-fissure structure, or a dendritic structure extending away from the surface of the first pores 261, but aspects are not limited thereto. Or, described another way, the first pores 261 may be defined by a surface having a high surface roughness, the surface roughness being provided by the second pores 262.

The inverse opal structures 150 and 250 described above may have a large specific surface area due to dual porosity caused by the first pores 161 and 261 and the nano-sized second pores 162 and 262 formed on the walls of the first pores 161 and 261. Thus, if the inverse opal structure 150 or 250 having a large specific surface area is used as a light scattering layer of a dye-sensitized solar cell, the amount of the dye may increase, and thus, the light scattering effects of the light scattering layer and functions of an electrode may be improved.

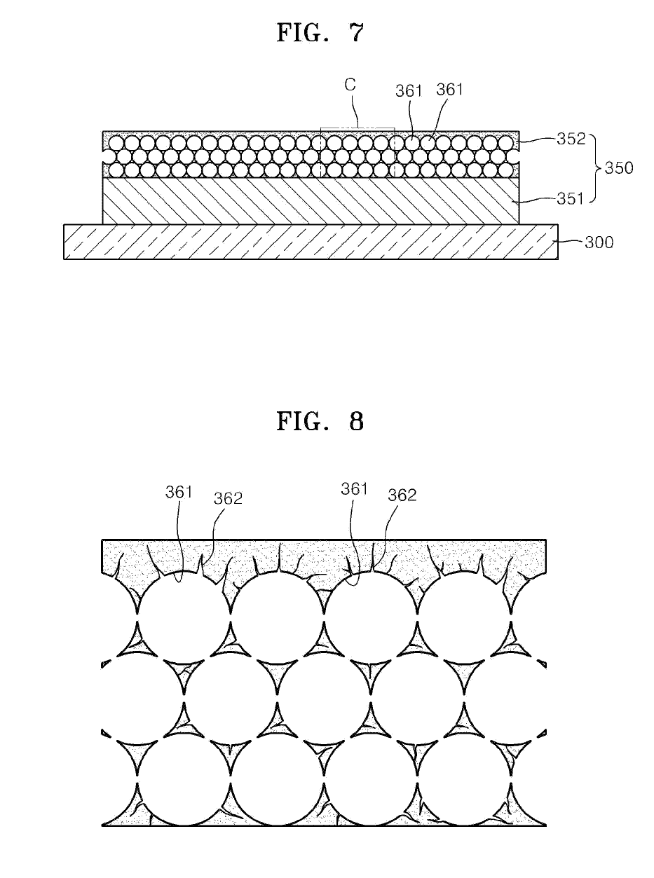

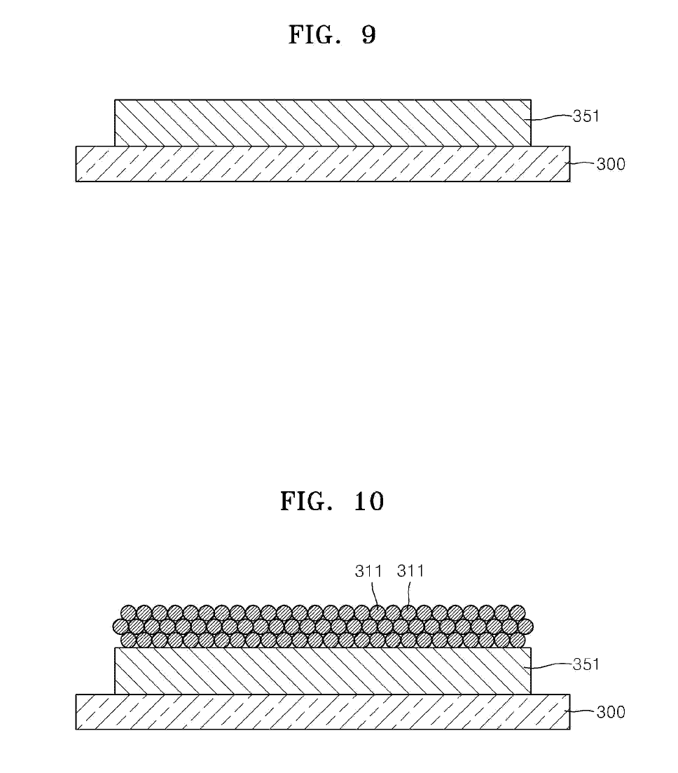

FIG. 7 schematically shows a dye-sensitized solar cell according to another embodiment of the invention. FIG. 8 is an enlarged view of portion C of FIG. 7. Referring to FIGS. 7 and 8, the dye-sensitized solar cell according to another embodiment of the invention includes a transparent conductive substrate 300 and a photoanode 350 disposed on the transparent conductive substrate 300. The photoanode 350 includes a light absorbing layer 351 including TiO₂, and a light scattering layer 352 disposed on the light absorbing layer 351 and including TiO₂.

The transparent conductive substrate 300 may be formed of, for example, indium tin oxide (ITO), but aspects of the invention are not limited thereto. The light absorbing layer 351 may be formed of nano crystalline TiO₂ film. The light absorbing layer 351 may be formed by coating a paste including TiO₂ nano particles having an average diameter ranging from about 10 nm to about 50 nm on the transparent conductive substrate 300. The light absorbing layer 351 may have a thickness of about 10 μm, but the invention is not limited thereto.

The light scattering layer 352 has an inverse opal structure with dual porosity as described above. The light scattering layer 352 includes a plurality of first pores 361 and a plurality of second pores 362. The light scattering layer 352 may be formed of TiO₂. The first pores 361 are regularly arranged in the photonic crystal structure and may have a spherical shape with an average diameter ranging from about 200 nm to about 400 nm, but aspects of the invention are not limited thereto. In addition, the second pores 362 formed on the walls of the first pores 361 have a nano-sized diameter. For example, the second pores 362 may have an average diameter ranging from about 2 nm to about 6 nm. The light scattering layer 352 may have a large specific surface area ranging from about 50 m²/g to about 100 m²/g due to the nano-sized second pores 362 formed on the walls of the first pores 361 that are regularly arranged. The light scattering layer 352 may have a thickness ranging from about 2 to about 10 μm, but aspects of the invention are not limited thereto.

As described above, due to the double porosity caused by the plurality of first and second pores 361 and 362, the light scattering layer 352 may have a large specific surface area, and accordingly, the amount of the dye adsorbed to the light scattering layer 352 may be increased. Furthermore, the increase of the amount of the adsorbed dye may improve light scattering effects and functions of an electrode of the dye-sensitized solar cell, thereby improving the efficiency of the dye-sensitized solar cell.

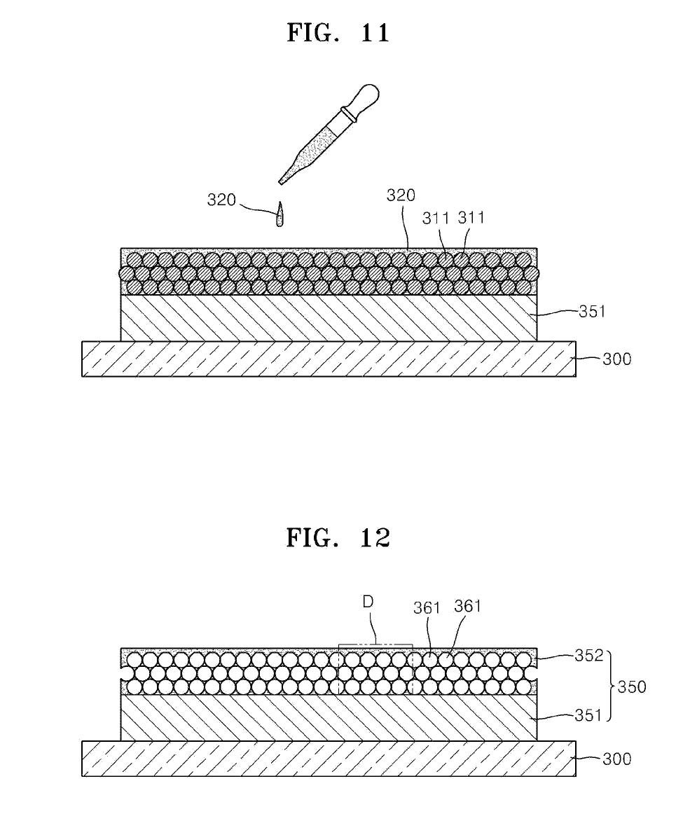

FIGS. 9 to 12 are views for describing a method of manufacturing the dye-sensitized solar cell shown in FIG. 7 according to another embodiment of the invention. Referring to FIG. 9, the light absorbing layer 351 is formed on the transparent conductive substrate 300. The light adsorbing layer 351 may be formed of a nano crystalline TiO₂ film. The light absorbing layer 351 may be formed by coating a paste including TiO₂ nano particles having an average diameter ranging from about 10 nm to about 50 nm on the transparent conductive substrate 300. The light absorbing layer 351 may have a thickness of about 10 μm, but aspects of the invention are not limited thereto.

Referring to FIG. 10, a plurality of photonic crystal particles 311 are regularly formed on the light absorbing layer 351. The photonic crystal particles 311 may be regularly arranged on the light absorbing layer 351 using an evaporation induced self assembly (EISA) but aspects are not limited thereto. The photonic crystal particles 311 may have a spherical shape with an average diameter ranging from about 200 nm to about 400 nm. The photonic crystal particles 311 may be formed of PMMA, polystyrene, silica, or the like, and are used as a template for manufacturing the light scattering layer 352 having an inverse opal structure that will be described later.

Referring to FIG. 11, a mixture solution 320 including a TiO₂ precursor and a surfactant is coated on the photonic crystal particles 311 regularly arranged on the light absorbing layer 351. The surfactant may be PLURONIC® P123 from BASF, cetyltrimethylammonium bromide (CTABr), or the like, but aspects of the invention are not limited thereto. The amount of the surfactant based on the amount of the TiO₂ precursor may be in the range of about 25 weight % to about 45 weight %. As such, when the mixture solution 320 including the TiO₂ precursor and the surfactant is coated on the photonic crystal particles 311, the mixture solution 320 fills the spaces between the photonic crystal particles 311. Then, the mixture solution 320 including the TiO₂ precursor and the surfactant and filled in the spaces between the photonic crystal particles 311 is aged at a relatively low temperature of about 4° C. for a time period of about 5 days. During the aging process, the surfactant contained in the mixture solution 320 is transferred to the peripheral area of the surface of the photonic crystal particles 311.

FIG. 12 shows the light scattering layer 352 formed on the light absorbing layer 351. An enlarged view of portion D of FIG. 12 is shown in FIG. 8. Referring to FIGS. 8 and 12, when the resultant shown in FIG. 11 is heat-treated at a temperature of about 400° C. for a time period of about 1 hour, the TiO₂ contained in the mixture solution 320 is crystallized, and the photonic crystal particles 311 and the surfactant are removed to form the light scattering layer 352. If the photonic crystal particles 311 are formed of PMMA or poly styrene, the crystallization of the TiO₂ and the removal of the photonic crystal particles 311 and the surfactant may be simultaneously performed by the heat-treatment. In this case, the surfactant formed on the surface of the photonic crystal particles 311 may be removed while the photonic crystal particles 311 are removed by the heat-treatment. If the photonic crystal particles 311 are formed of silica, the crystallization of the TiO₂ and the removal of the surfactant may be performed by the heat-treatment, and the removal of the photonic crystal particles 311 may be performed by using an etchant, e.g., a NaOH solution.

In the light scattering layer 352, a plurality of first pores 361 are formed by removing the photonic crystal particles 311, and a plurality of second pores 362 are formed by removing the surfactant. The first pores 361 may have an average diameter ranging from about 200 to about 400 nm corresponding to the size of the photonic crystal particles 311, and the second pores 362 may be formed on the walls of the first pores 361 with an average diameter ranging from about 2 to about 6 nm.

Then, the resultant shown in FIG. 12 is immersed in a photosensitive dye (not shown) for a time period of about 24 hours. Then, an electrolyte (not shown) is injected between a transparent conductive substrate (not shown) coated with Pt and the photoanode 350 to which the photosensitive dye molecules are adsorbed to complete the manufacture of the dye-sensitized solar cell.

As described above, according to aspects of the invention, the specific surface area of an inverse opal structure may increase by forming nano-sized pores in the inverse opal structure. Accordingly, if the inverse opal structure having a dual porosity is used as a light scattering layer of a dye-sensitized solar cell, the amount of the adsorbed dye may increase, and thus the light scattering effects of the light scattering layer and functions of electrodes may be improved.

Although a few embodiments of the invention have been shown and described, it would be appreciated by those skilled in the art that changes may be made in these embodiments without departing from the principles and spirit of the invention, the scope of which is defined in the claims and their equivalents.

What is claimed is:

1. An inverse opal structure comprising:
a plurality of first pores regularly arranged in a photonic crystal structure; and
a plurality of second pores formed on walls of the first pores and having a nano-sized diameter.

2. The inverse opal structure of claim 1, wherein the first pores have a spherical shape.

3. The inverse opal structure of claim 1, wherein the first pores have an average diameter ranging from about 200 nm to about 400 nm.

4. The inverse opal structure of claim 1, wherein the second pores have an average diameter ranging from about 2 nm to about 6 nm.

5. The inverse opal structure of claim 1, wherein the inverse opal structure has a specific surface area ranging from about 50 m²/g to about 100 m²/g.

6. The inverse opal structure of claim 1, wherein the inverse opal structure includes a semiconductor oxide.

7. The inverse opal structure of claim 1, wherein the second pores have a dendritic structure and extend from the walls of the first pores into the inverse opal structure.

8. A method of manufacturing an inverse opal structure, the method comprising:
arranging a plurality of photonic crystal particles in a regular pattern;
coating a mixture solution, comprising a semiconductor oxide precursor and a surfactant, on the photonic crystal particles to fill spaces between the photonic crystal particles;
crystallizing semiconductor oxide from the semiconductor oxide precursor;
removing the photonic crystal particles; and
removing the surfactant.

9. The method of claim 8, wherein a plurality of first pores are formed by the removing of the photonic crystal particles, and a plurality of second pores are formed by the removing of the surfactant.

10. The method of claim 9, wherein the second pores are formed on walls of each of the first pores.

11. The method of claim 9, wherein the first pores have an average diameter ranging from about 200 nm to about 400 nm.

12. The method of claim 8, wherein the photonic crystal particles include poly(methyl methacrylate) (PMMA), poly styrene, and/or silica.

13. The method of claim 12, wherein the photonic crystal particles are formed of PMMA or poly styrene, and the crystallizing of the semiconductor oxide and the removing of the photonic crystal particles and the removing of the surfactant are performed by heat-treatment.

14. The method of claim 12, wherein the photonic crystal particles are formed of silica, and the crystallizing of the semiconductor oxide and the removing of the surfactant are performed by heat treatment, and the removing of the photonic crystal particles is performed by etching.

15. A dye-sensitized solar cell comprising:
a transparent conductive substrate;
a light absorbing layer comprising TiO₂ and formed on the transparent conductive substrate; and
a light scattering layer formed on the light absorbing layer, the light scattering layer having an inverse opal structure comprising a plurality of first pores regularly arranged in a photonic crystal structure, and a plurality of second pores formed on walls of the first pores, the second pores having a nano-sized diameter.

16. The dye-sensitized solar cell of claim 15, wherein the first pores have an average diameter ranging from about 200 nm to about 400 nm, and the second pores have an average diameter ranging from about 2 nm to about 6 nm.

17. The dye-sensitized solar cell of claim 15, wherein the light scattering layer has a specific surface area ranging from about 50 m²/g to about 100 m²/g.

18. The dye-sensitized solar cell of claim 15, wherein the light scattering layer has a thickness ranging from about 2 μm to about 10 μm.

19. The dye-sensitized solar cell of claim 15, wherein the light absorbing layer is a nanocrystalline TiO₂ layer.

20. The dye-sensitized solar cell of claim 15, wherein the light scattering layer comprises TiO₂ or ZnO.

21. A method of manufacturing a dye-sensitized solar cell, the method comprising:
forming a light absorbing layer comprising TiO₂ on a transparent conductive substrate;
forming a light scattering layer on the light absorbing layer, the forming of the light scattering layer comprising:
arranging a plurality of photonic crystal particles regularly on the light absorbing layer,
coating a mixture solution comprising a semiconductor oxide precursor and a surfactant on the photonic crystal particles to fill spaces between the photonic crystal particles,
crystallizing a semiconductor oxide from the semiconductor oxide precursor,
removing the photonic crystal particles, and
removing the surfactant.

22. The method of claim 21, wherein the light absorbing layer is formed by coating a paste including TiO₂ nanoparticles on the transparent conductive substrate.

23. The method of claim 21, wherein a plurality of first pores are formed by the removing of the photonic crystal particles, and a plurality of second pores are formed by the removing of the surfactant.

24. The method of claim 23, wherein the second pores are formed on walls of each of the first pores.

25. The method of claim 23, wherein the first pores have an average diameter ranging from about 200 nm to about 400 nm, and the second pores have an average diameter ranging from about 2 nm to about 6 nm.

26. The method of claim 21, wherein the photonic crystal particles include poly(methyl methacrylate) (PMMA), poly styrene, and/or silica.

27. The method of claim 21, wherein the semiconductor oxide precursor is a TiO₂ precursor or a ZnO precursor.
